(19) United States
(12) Patent Application Publication
(10) Pub. No.: US 2007/0004141 A1
(43) Pub. Date: Jan. 4, 2007

(54) Method of manufacturing flash memory device

(75) Inventors: Nam Kyeong Kim, Kyeongki-do (KR); Eun Seok Choi, Kyeongki-do (KR); Sang Hyun Oh, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/479,285

(22) Filed: Jun. 30, 2006

(30) Foreign Application Priority Data
Jul. 4, 2005 (KR) 2005-59855
Dec. 14, 2005 (KR) 2005-122895

(51) Int. Cl. H01L 21/336

(52) U.S. Cl. 438/257

(57) ABSTRACT

A method of manufacturing a flash memory device which can improve capacitance and can reduce the interference phenomenon. According to one embodiment, a method of manufacturing a flash memory device includes the steps of depositing a tunnel oxide layer over a semiconductor substrate having a isolation structure, depositing a conductive layers for a floating gate over the tunnel oxide layer, forming an oxide layer between the conductive layers for the floating gate, forming a recess pattern in the conductive layers for the floating gate, and depositing a dielectric layer and a conductive layer for a control gate, respectively.

### BACKGROUND

The invention relates generally to a method of manufacturing a flash memory device and more particularly, to a method of manufacturing a flash memory device, wherein capacitance can be interposed and the interference phenomenon can be reduced.

In general, a flash memory device is a device that stores and reads data on the basis of variation in the threshold voltage when electrons are injected into a floating gate and when electrons are not injected into the floating gate. As the degree of integration of devices is increased, rapid operating speed and high data reliability of the flash memory device are required. To this end, it is necessary to increase the capacitance.

To increase the capacitance of the flash memory device, there have been proposed a method of using a high dielectric material as the dielectric layer formed between the floating gate and the control gate, a method of reducing the thickness of the dielectric layer, a method of increasing the coupling ratio by increasing the height of the floating gate, and so on.

If the high dielectric material is used as the dielectric layer, however, the interface trap characteristic is degraded and the threshold voltage is abruptly shifted, resulting in low reliability of the devices. Accordingly, it is difficult to apply the method. Furthermore, if the thickness of the dielectric layer is reduced, the breakdown voltage is lowered, which has a direct effect on data failure. Accordingly, there is a limit to a reduction of the thickness of the dielectric layer.

In addition, if the height of the floating gate is increased, the interference phenomenon between neighboring floating gates becomes more significant and cell distributions are widened accordingly. As a result, it is difficult to secure the characteristics and uniformity of the devices.

### SUMMARY OF THE INVENTION

In one embodiment, the invention provides a method of manufacturing a flash memory device, which can improve capacitance and reduce the interference phenomenon.

According to an aspect of the invention, a method of manufacturing a flash memory device includes the steps of depositing a tunnel oxide layer over a semiconductor substrate having a isolation structure, depositing a conductive layers for a floating gate over the tunnel oxide layer, forming an oxide layer between the conductive layers for the floating gate, forming a recess pattern in the conductive layers for the floating gate, and depositing a dielectric layer and a conductive layer for a control gate, respectively.

The conductive layers for the floating gates may preferably be formed using any one of a polysilicon layer, W, WN, Ti, TiN, Pt, Ru, RuO₂, Ir, IrO₂, and Al, or combination thereof. The polysilicon layer may preferably be formed to a thickness of 100 Å to 5000 Å at a temperature of 250° C. to 1000° C.

The conductive layers for the floating gates may preferably be formed by a chemical vapor deposition (CVD) method or an atomic layer deposition (ALD) method.

The oxide layer may preferably be formed using any one of a high density plasma (HDP) oxide layer, plasma enhanced-tetra ethyl ortho silicate (PE-TEOS), high temperature oxide (HTO), an advanced planarization layer (APL) oxide layer.

The recess patterns may preferably be formed by etching the conductive layers for the floating gates to a thickness of 100 Å to 5000 Å, preferably using Cl and F.

The dielectric layer may preferably be formed to a thickness of 20 Å to 1000 Å by using an ONO (oxide nitride oxide) layer, a single layer, such as Al₂O₃, HfO₂ or ZrO₂, or a multi-layer structure in which two or more of Al₂O₃, HfO₂, and ZrO₂ are laminated. The oxide layer of the ONO may preferably be formed to a thickness of 5 Å to 100 Å and the nitride layer of the ONO is preferably formed to a thickness of 10 Å to 100 Å.

The conductive layer for the control gate may preferably be formed by laminating a polysilicon layer and a metal layer. The polysilicon layer may preferably be formed to a thickness of 100 Å to 5000 Å, and the metal layer is preferably formed to a thickness of 100 Å to 3500 Å, preferably using any one of W, WN, Pt, Ir, Ru, and Te.

A hard mask layer may be further formed on the conductive layer for the control gate. The hard mask layer may preferably be formed using either Si₃N₄ or Si—N. The Si₃N₄ layer may preferably be formed by a furnace method and the Si—N is preferably formed by a plasma method.

According to another aspect, the invention provides a method of manufacturing a flash memory device, including the steps of forming a trench in a semiconductor substrate in which a tunnel oxide layer, a conductive layer, and a hard mask layer are laminated, forming isolation structures to fill the trench using isolation material, removing the hard mask layer to expose a top surface of the isolation structures, and forming conductive layer spacers on each sides of the isolation structures.

The method may further include the steps of after the floating gate is formed, removing a predetermined thickness of the isolation structures, and forming a dielectric layer and a conductive layer for a control gate on the entire surface including the floating gate.

The conductive layer and the conductive layer spacers may preferably be formed using a polysilicon layer.

The conductive layer spacers may preferably be formed by depositing a conductive layer on the entire structure from which the hard mask layer has been removed and then blanket-etching the conductive layer.

The conductive layer may preferably be formed to a thickness of 1 nm to 100 nm. The conductive layer spacers may preferably have a width, which is 1/20 to ⅓ smaller than that of the first conductive layer. The active region may preferably have a width greater than that of the field region.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A to 1D are cross-sectional views illustrating a method of manufacturing a flash memory device according to a first embodiment of the invention; and

FIGS. 2A to 2F are cross-sectional views illustrating a method of manufacturing a flash memory device according to a second embodiment of the invention.

### DETAILED DESCRIPTION OF EMBODIMENTS

The invention is described below in detail in connection with certain exemplary embodiments with reference to the accompanying drawings.

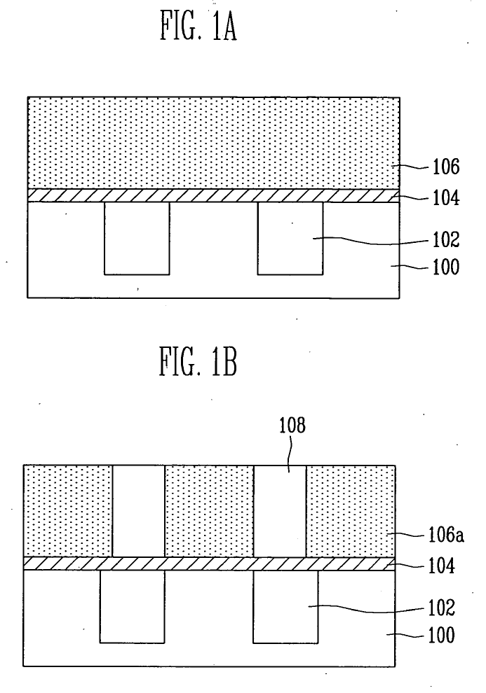

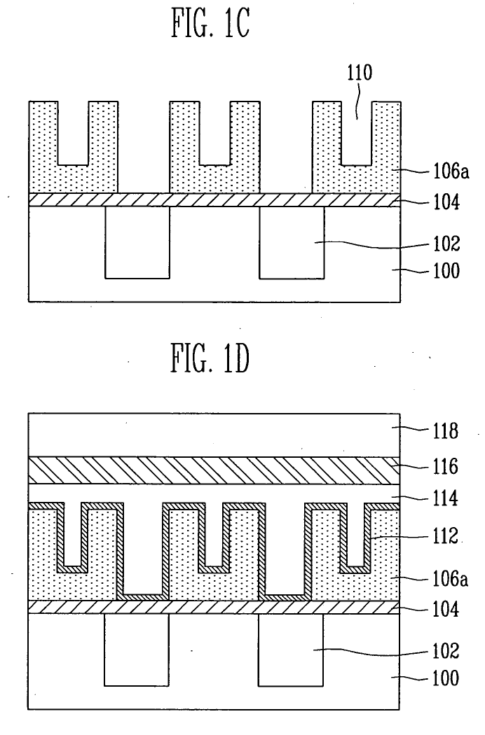

FIGS. 1A to 1D are cross-sectional views illustrating a method of manufacturing a flash memory device according to a first embodiment of the invention.

Referring to FIG. 1A, a tunnel oxide layer 104 and a conductive layer 106 for a floating gate are sequentially deposited on a semiconductor substrate 100 in which isolation structures 102 are formed. The conductive layer 106 may be preferably formed using any one of a polysilicon layer, W, WN, Ti, TiN, Pt, Ru, RuO₂, Ir, IrO₂, and Al, or combination thereof by means of a CVD method or an ALD method. More particularly, the doped polysilicon layer may be preferably formed to a thickness of 100 Å to 5000 Å at a temperature of 250° C. to 1000° C.

Referring to FIG. 1B, a first photoresist pattern (not shown) is formed on the conductive layer 106 over the isolation structures 102. The conductive layer 106 is etched using the first photoresist pattern as a mask, thus forming conductive layer patterns 106a. The first photoresist pattern is stripped and an oxide layer 108 is then formed on the entire surface so that between-the conductive layer patterns 106a are buried. A planarization process is then performed until the conductive layer patterns 106a are exposed.

The oxide layer 108 may be preferably formed using any one of a HDP oxide layer, PE-TEOS, HTO, an APL oxide layer. The planarization process may preferably use a CMP process of an etch-back process.

The process of forming the oxide layer 108 is performed to prevent the misalignment of a second photoresist pattern through which the central portions of the conductive layer patterns 106a are exposed when recess patterns are subsequently formed by etching the central portions of the conductive layer patterns 106a.

Referring to FIG. 1C, the second photoresist pattern (not shown) through which the central portions of the conductive layer patterns 106a are exposed is formed. The conductive layer patterns 106a are partially etched using the second photoresist pattern as a mask, thereby forming recess patterns 110. When the conductive layer patterns 106a are etched, Cl and F are preferably be used as an etch gas. An etch depth of each conductive layer pattern 106a is preferably set to 100 Å to 5000 Å.

Thereafter, the second photoresist pattern is stripped and the oxide layer 108 is removed by a wet etch process, thus forming a floating gate having the conductive layer pattern 106a whose both edges are projected higher than its central portion. The floating gate having a wide surface area can be secured.

Referring to FIG. 1D, a dielectric layer 112 is formed on the entire surface including the conductive layer patterns 106a. The dielectric layer 112 may have an ONO structure in which an oxide layer, a nitride layer, and an oxide layer preferably of 20 Å to 1000 Å in thickness are laminated, a single layer employing a high dielectric material, such as Al₂O₃, HfO₂ or ZrO₂, for example, or a multi-layer structure in which two or more of Al₂O₃, HfO₂, and ZrO₂ for exampler, are laminated.

In the case where the dielectric layer 112 has the ONO structure, the oxide layer may be preferably formed to a thickness of 5 Å to 100 Å and the nitride layer may be preferably formed to a thickness of 10 Å to 100 Å.

A polysilicon layer 114 (i.e., a conductive layer for a control gate) and a metal layer 116 are sequentially formed on the dielectric layer 112. After a hard mask layer 118 is formed on the metal layer 116, the lamination structures from the hard mask layer 118 to the conductive layer patterns 106a are patterned to form gates. The polysilicon layer 114 is preferably formed to a thickness of 100 Å to 5000 Å, the metal layer 116 is preferably formed to a thickness of 100 Å to 3500 Å using any one of W, WN, Pt, Ir, Ru, and Te, and the hard mask layer 118 is preferably formed using a nitride layer, such as Si₃N₄ or Si—N. Si₃N₄ may be formed using a furnace method and Si—N may be formed using a plasma method, for example.

The fabrication of the flash memory device according to the first embodiment of the invention is thereby completed.

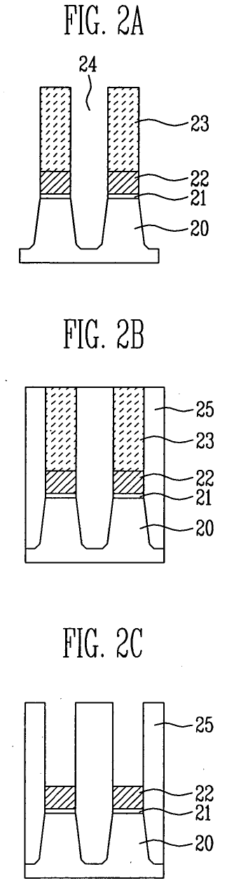

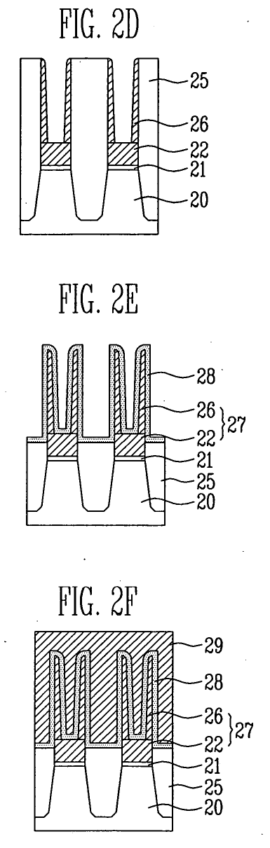

FIGS. 2A to 2F are cross-sectional views illustrating a method of manufacturing a flash memory device according to a second embodiment of the invention.

Referring to FIG. 2A, a tunnel oxide layer 21, a first conductive layer 22 for a floating gate, and a hard mask layer 23 are sequentially formed on a semiconductor substrate 20. The hard mask layer 23, the first conductive layer 22, the tunnel oxide layer 21, and a predetermined depth of the semiconductor substrate 20 are etched to form a trench 24. A lateral oxidization process is performed in order to remove damage that has occurred during the etch process of the trench 24. The first conductive layer 22 may be formed using a polysilicon layer and the hard mask layer 23 may be formed using a nitride layer.

To facilitate the etch process of the trench, a hard mask layer may be further formed on the hard mask layer 23. The hard mask layer may be patterned and a trench etch process using the patterned hard mask layer as a mask may be then performed.

Referring to FIG. 2B, an oxide layer is formed on the entire structure so that the trench 24 is buried. A planarization process is performed on the oxide layer so that the hard mask layer 23 is exposed. Accordingly, an isolation structure 25 is formed in the trench 24 to define an active region and a field region.

Referring to FIG. 2C, the hard mask layer 23 is striped to expose the top surface of the first polysilicon layer 22 and the sides of the isolation structures 25.

Referring to FIG. 2D, a second conductive layer is deposited on the entire surface. The second conductive layer is etched by a blanket etch-back process to form conductive layer spacers 26 on the sides of the exposed isolation structures 25, thereby forming a floating gate 27 having the first conductive layer 22 and the conductive layer spacers 26.

The second conductive layer is preferably formed to a thickness of 1 nm to 100 nm using a polysilicon layer and the conductive layer spacers 26 may have a width, which is preferably 1/20 to ⅓ smaller than that of the first conductive layer 22.

Referring to FIG. 2E, a predetermined thickness of the isolation structures 25 is etched by a wet etch process in order to lower the EFH (effective field height). A dielectric layer 28 is then formed on the entire surface. At this time, a wet process may be performed so that the top surface of the isolation structures 25 is lower than that of the first conductive layer 22. The dielectric layer 28 may be formed using an ONO layer.

Referring to FIG. 2F, a polysilicon layer and a metal layer are sequentially laminated on the dielectric layer 28, forming a conductive layer 29 for a control gate. The polysilicon layer may be formed to a thickness of 100 Å to 5000 Å and the metal layer may be formed to a thickness of 100 Å to 3500 Å, preferably using any one of W, WN, Pt, Ir, Ru, and Te.

Thereafter, though not shown in the drawings, the conductive layer 29 for the control gate, the gate dielectric layer 28, and the floating gate 27 are selectively etched by a photolithography process, forming a gate.

The fabrication of the flash memory device according to the second embodiment of the invention is thereby completed.

If the distance between the conductive layer spacers 26 is narrowed due narrow technology, it is expected that it is difficult to form the gate dielectric layer 28 and the conductive layer 29 for the control gate between the conductive layer spacers 26. For this reason, the above-mentioned second embodiment proposes a third embodiment of the invention, in which the width of the active region is significantly modified compared with the isolation structure.

If the width of the active region is increased, the distance between the conductive layer spaces is increased and the margin of a process of forming the dielectric layer and the conductive layer for the control gate is formed accordingly. The remaining technical constitutions except that the active region has a width greater than that of the isolation structures in the third embodiment are the same as those of the second embodiment.

In the invention, the floating gate has both edges projected higher than its central portion by etching the central portion of the conductive layer for the floating gate or forming the conductive layer spacers at both edges of the conductive layer for the floating gate. Accordingly, the coupling ratio can be increased 40% or more in comparison with the related art. Therefore, since the capacitance of the flash memory device can be increased, the program rate can be enhanced and the reliability of devices can be improved.

Furthermore, in the case where capacitance is required, the cross section of the floating gate in a bit line direction can be reduced. It is therefore possible to reduce the interference between cells adjacent in the bit line direction by up to 40% or more. In addition, since the distance between cells adjacent in the word line direction is also increased, the interference between cells adjacent in the word line direction can be reduced. It is therefore possible to reduce a total interference phenomenon by half compared with the related art.

As described, the invention has the following advantages.

First, since the surface area of the floating gate is widened, the overlapped area between the floating gate and the control gate can be increased. Accordingly, the capacitance of the flash memory device can be increased.

Second, since the capacitance is increased, the program rate can be enhanced and the reliability of devices can be improved.

Third, the cross sections of floating gates adjacent in the bit line direction can be reduced and the cross sections of floating gates adjacent in the word line direction can be increased. Accordingly, the interference phenomenon can be reduced.

Fourth, since the interference phenomenon can be reduced, cell distributions can be reduced. Accordingly, high-integrated devices and multi-level cell devices can be fabricated more easily.

While the invention has been described in connection with practical exemplary embodiments the invention is not limited to the disclosed embodiments but, to the contrary, is intended to cover various modifications and equivalent arrangements included within the spirit and scope of the appended claims.

What is claimed is:

1. A method of manufacturing a flash memory device, comprising:
depositing a tunnel oxide layer over a semiconductor substrate having a isolation structure;
depositing a conductive layers for a floating gate over the tunnel oxide layer;
forming an oxide layer between the conductive layers for the floating gate;
forming a recess pattern in the conductive layers for the floating gate; and
depositing a dielectric layer and a conductive layer for a control gate, respectively.

2. The method of claim 1, comprising forming the conductive layers for the floating gates are selected from a polysilicon layer, W, WN, Ti, TiN, Pt, Ru, RuO₂, Ir, IrO₂, and Al, or combination thereof.

3. The method of claim 2, comprising forming the polysilicon layer is formed to a thickness of 100 Å to 5000 Å at a temperature of 250° C. to 1000° C.

4. The method of claim 1, comprising forming the conductive layers for the floating gates by a chemical vapor deposition (CVD) method or an atomic layer deposition (ALD) method.

5. The method of claim 1, comprising forming the oxide layer using any one of a high density plasma (HDP) oxide layer, plasma enhanced-tetra ethyl ortho silicate (PE-TEOS), high temperature oxide (HTO), an advanced planarization layer (APL) oxide layer.

6. The method of claim 1, comprising forming the recess patterns by etching the conductive layers for the floating gates to a thickness of 100 Å to 5000 Å using Cl and F.

7. The method of claim 1, comprising forming the dielectric layer to a thickness of 20 Å to 1000 Å.

8. The method of claim 1, comprising forming the dielectric layer using an ONO (oxide nitride oxide) layer, a single layer, structure formed of a member selected from the group consisting of Al₂O₃, HfO₂ and ZrO₂, or a multi-layer structure formed of two or more laminated layers of Al₂O₃, HfO₂, or ZrO₂.

9. The method of claim 8, comprising forming the oxide layer of the ONO to a thickness of 5 Å to 100 Å and forming the nitride layer of the ONO to a thickness of 10 Å to 100 Å.

10. The method of claim 1, comprising forming the conductive layer for the control gate is formed by laminating a polysilicon layer and a metal layer.

11. The method of claim 10, comprising forming the polysilicon layer to a thickness of 100 Å to 5000 Å, and forming the metal layer to a thickness of 100 Å to 3500 Å using any one of the group consisting of W, WN, Pt, Ir, Ru, and Te.

12. The method of claim 1, comprising further forming a hard mask layer formed on the conductive layer for the control gate.

13. The method of claim 12, comprising forming the hard mask layer is formed using either Si₃N₄ or Si—N.

14. The method of claim 13, comprising forming the Si₃N₄ layer by a furnace method and forming the Si—N by a plasma method.

15. The method of claim 1, wherein the recess pattern is formed by etching a central portion of the conductive layers for the floating gate.

16. The method of claim 1, both edges of the floating gate are projected higher than a central portion thereof.

17. A method of manufacturing a flash memory device, comprising:
forming a trench in a semiconductor substrate in which a tunnel oxide layer, a conductive layer, and a hard mask layer are laminated;
forming isolation structures to fill the trench using isolation materal;
removing the hard mask layer to expose a top surface of the isolation structures; and
forming conductive layer spacers on each sides of the isolation structures.

18. The method of claim 17, further comprising the steps of:
after the floating gate is formed, removing a predetermined thickness of the isolation structures; and
forming a dielectric layer and a conductive layer for a control gate on the entire surface including the floating gate.

19. The method of claim 17, comprising forming the conductive layer and the conductive layer spacers using a polysilicon layer.

20. The method of claim 17, comprising forming the conductive layer spacers by depositing a conductive layer over the conductive layer and the isolation structures, and then blanket-etching the conductive layer.

21. The method of claim 20, comprising forming the conductive layer to a thickness of 1 nm to 100 nm.

22. The method of claim 17, wherein the conductive layer spacers have a width, which is 1/20 to ⅓ smaller than that of the first conductive layer.

23. The method of claim 17, wherein the active region has a width greater than that of the field region.

24. The method of claim 18, wherein the control gate is formed of metal, metal-silicide and combination thereof.

25. The method of claim 17, wherein the hard mask layer is formed of a nitride layer.

26. The method of claim 17, wherein the hard mask layer is removed by a wet etching process.

27. The method of claim 18, wherein a EFH of the isolation structure is lower than the floating gate.
